(19) United States
(12) Patent Application Publication
(10) Pub. No.: US 2009/0302315 A1
(43) Pub. Date: Dec. 10, 2009

(54) Resistive random access memory

(75) Inventors: Changbum Lee, Seoul (KR); Youngsoo Park, Yongin-si (KR); Myoungjae Lee, Suwon-si (KR); Bosoo Kang, Seoul (KR); Seungeon Ahn, Suwon-si (KR); Kihwan Kim, Anyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/379,719

(22) Filed: Feb. 27, 2009

(30) Foreign Application Priority Data
Jun. 4, 2008 (KR) 10-2008-0052666

(51) Int. Cl. H01L 29/12; H01L 29/00

(52) U.S. Cl. 257/43; 257/536; 257/E29.001; 257/E29.068

(57) ABSTRACT

A resistive random access memory (RRAM) includes a switch region formed of a material having bi-polar properties; and a memory resistor formed of a material having uni-polar properties. The RRAM further includes a lower electrode formed below the switch region; an upper electrode formed on the memory resistor; and an intermediate electrode formed between the switch region and the memory resistor.

### CROSS-REFERENCE TO RELATED APPLICATION

This application claims priority under 35 U.S.C. §119 to Korean Patent Application No. 10-2008-0052666, filed on Jun. 4, 2008, in the Korean Intellectual Property Office, the disclosure of which is incorporated herein in its entirety by reference.

### BACKGROUND

1. Field

One or more example embodiments relate to memories such as resistive random access memories (RRAMs) including a switch structure.

2. Description of the Related Art

A conventional semiconductor memory array includes many memory cells connected through a given or predetermined circuit structure. A conventional dynamic random access memory (DRAM), which is a representative example of a semiconductor memory array, includes a single switch and a single capacitor. A conventional DRAM is a highly integrated, relatively rapid memory device. However, conventional DRAMs are volatile memories, which do not retain data when power is shut off. On the other hand, a nonvolatile memory device is capable of retaining data even after power is shut off. A flash memory is a representative example of a conventional nonvolatile memory device. Conventional flash memories, however, cannot be as highly integrated, and have a relatively low operating speed when compared with conventional DRAMs.

Examples of conventional nonvolatile memory devices include magnetic random access memories (MRAMs), ferroelectric random access memories (FRAMs), phase-change random access memories (PRAMs), and resistive random access memories (RRAMs). RRAMs use variable resistive properties (or resistance characteristics) of transition metal oxides (TMOs), which are properties of resistance that vary according to an applied voltage.

A conventional RRAM includes a memory resistor and a switch structure. The memory resistor is formed of a TMO having variable resistive properties. A transistor or a diode is used as a conventional switch structure. A conventional diode is a bilayer structure formed of p-type and n-type semiconductor materials, and is used in a conventional cross-point type memory structure.

### SUMMARY

One or more example embodiments provide a resistive random access memory (RRAM) including a switch structure, which does not require a diode or transistor structure.

One or more example embodiments provide a resistive random access memory (RRAM), which may include a switch region formed of a material having bi-polar properties, and a memory resistor formed of a material having uni-polar properties. The switch region may be formed of at least one of SiO₂, CuO, SrZrO₃, SrTiO₃, SrLaTiO₃, PrCaMnO, ZrO₂, TiO₂, TiON, a combination thereof or the like. The memory resistor may include at least one of a Ni oxide, a Ni oxide doped with Ti, a Co oxide, a Hf oxide, a Zn oxide, a W oxide, a Nb oxide, an Al oxide, a V oxide, a Cr oxide, a Fe oxide, a Ta oxide, a combination thereof or the like.

According to at least some example embodiments, the RRAM may further include a lower electrode formed below the switch region, an upper electrode formed on the memory resistor, and an intermediate electrode formed between the switch region and the memory resistor.

At least one other example embodiment provides an RRAM, which may include a switch region and a memory resistor. The switch region may include an intermediate layer including an electrolyte, and a nano bridge formed on the intermediate layer. The memory resistor may have variable resistance properties. According to at least some example embodiments, the intermediate layer may be formed of AgS, As₂S, GsSe, a combination thereof or the like. The nano bridge may be formed of Ag or the like. The memory resistor may include at least one of a Ni oxide, a Ni oxide doped with Ti, a Co oxide, a Hf oxide, a Zn oxide, a W oxide, a Nb oxide, an Al oxide, a V oxide, a Cr oxide, a Fe oxide, a Ta oxide, a combination thereof or the like. The switch region may not be a diode having a bilayer structure, may not constitute a diode and/or may not constitute a transistor. Thus, the RRAM may omit a transistor or diode as a switching device.

According to at least some example embodiments, the switch region may be formed of a nano switch material. The nano switch material may be formed of a quantized conductance atomic switch (QCAS) material.

At least one other example embodiment provides a multi-layer RRAM structure including a plurality of RRAMs arranged in an array. Each RRAM may include a switch region formed of a material having bi-polar properties, and a memory resistor formed of a material having uni-polar properties.

At least one other example embodiment provides a multi-layer RRAM structure including a plurality of RRAMs arranged in an array. Each RRAM may include a switch region and a memory resistor. The switch region may include an intermediate layer including an electrolyte, and a nano bridge formed on the intermediate layer. The memory resistor may have variable resistance properties.

At least one other example embodiment provides a multi-layer RRAM structure including a plurality of RRAMs arranged in an array. At least one RRAM may include a switch region formed of a material having bi-polar properties, and a memory resistor formed of a material having uni-polar properties. At least one other RRAM may include a switch region including an intermediate layer having an electrolyte, and a nano bridge formed on the intermediate layer; and a memory resistor having variable resistance properties.

### BRIEF DESCRIPTION OF THE DRAWINGS

These and/or other aspects will become apparent and more readily appreciated from the following description of example embodiments, taken in conjunction with the accompanying drawings of which:

FIG. 1 is a cross-sectional view of a resistive random access memory (RRAM) according to an example embodiment;

FIG. 2A is a graph of electrical properties of a memory resistor of FIG. 1;

FIG. 2B is a graph of electrical properties of a switch region of FIG. 1;

FIG. 2C is a graph of electrical properties of the RRAM of FIG. 1;

FIG. 3 is a cross-sectional view of a RRAM according to another example embodiment;

FIG. 4A is a cross-sectional view of the RRAM of FIG. 3 in the case where switch regions are switched off;

FIGS. 4B and 4C are cross-sectional views of the RRAM of FIG. 3 in the case where the switch regions are switched on;

FIG. 5 is a graph illustrating electrical properties of the RRAM of FIG. 3; and

FIG. 6 illustrates the case where RRAMs, each of which corresponds to the RRAM of FIG. 1, are arranged in a multi-array structure, according to an example embodiment.

### DETAILED DESCRIPTION OF EXAMPLE EMBODIMENTS

Reference will now be made in detail to example embodiments which are illustrated in the accompanying drawings, wherein like reference numerals refer to the like elements throughout. In this regard, example embodiments may have different forms and should not be construed as being limited to the descriptions set forth herein. Accordingly, the example embodiments are merely described below, by referring to the figures, to explain aspects of the present description. In the drawings, the thicknesses of layers and regions are exaggerated for clarity.

Detailed example embodiments are disclosed herein. However, specific structural and functional details disclosed herein are merely representative for purposes of describing example embodiments. The present inventive concept may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the present inventive concept. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

Further, it will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

Further still, it will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

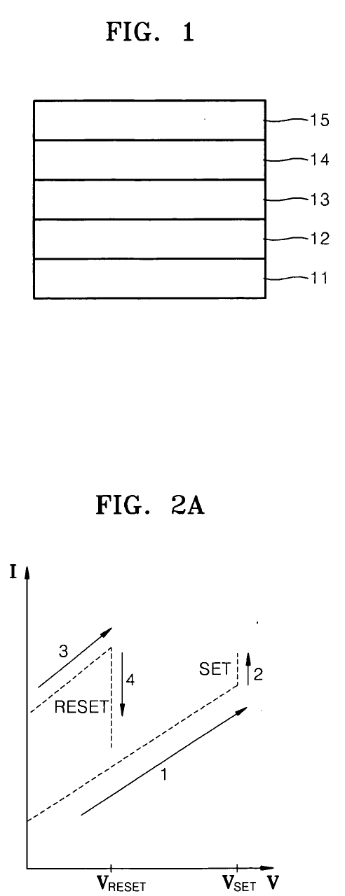

FIG. 1 is a cross-sectional view of a resistive random access memory (RRAM) according to an example embodiment. The RRAM shown in FIG. 1 may also be referred to as an RRAM cell.

Referring to FIG. 1, a switch region 12 may be formed on a lower electrode 11. An intermediate electrode 13, a memory resistor 14 and an upper electrode 15 may be formed sequentially on the switch region 12.

The lower electrode 11, the intermediate electrode 13 and the upper electrode 15 may be formed of a conductive material used to form a semiconductor device. For example, the lower electrode 11, the intermediate electrode 13 and the upper electrode 15 may be formed of Al, Hf, Zr, Zn, W, Co, Au, Ag, Pd, Pt, Ru, Ir, Ti or a conductive metal oxide. The memory resistor 14 may be formed of a variable resistive material used to form the RRAM. The variable resistive material has at least two properties, which vary according to a supplied current. The variable resistive material may be formed of a transition metal oxide (TMO). The operating characteristics of the memory resistor 14 will be described in more detail below. According to at least some example embodiments, the variable resistive material may be formed of a Ni oxide, a Ni oxide doped with Ti, a Co oxide, a Hf oxide, a Zn oxide, a W oxide, a Nb oxide, an Al oxide, a V oxide, a Cr oxide, a Fe oxide, a Ta oxide, a combination thereof or the like.

According to at least this example embodiment, the switch region 12 is not a diode or transistor having a bilayer structure, which is used in conventional memory devices, but is formed of a material having bi-polar resistance characteristics (or resistance change properties). In one example embodiment, the switch region 12 may be formed of a material having bi-polar resistance characteristics such as SiO₂, CuO, SrZrO₃, SrTiO₃, SrLaTiO₃, PrCaMnO, ZrO₂, TiO₂ or TiON.

According to at least this example embodiment, the RRAM may be manufactured using a semiconductor process method such as chemical vapor deposition (CVD), physical vapor deposition (PVD), atomic layer deposition (ALD), or the like.

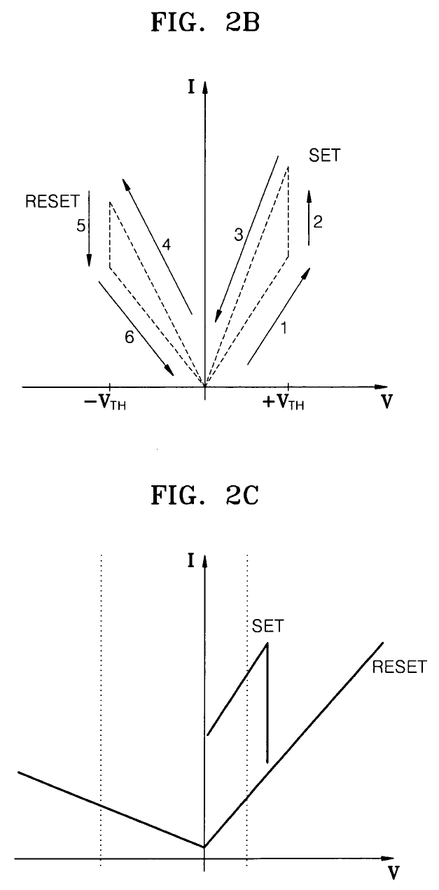

With reference to FIGS. 2A through 2C, an operating principle of the RRAM will be described. FIG. 2A is a graph of current with respect to voltage applied to the memory resistor 14 of FIG. 1.

Referring to FIG. 2A, the memory resistor 14 exhibits uni-polar properties or characteristics in which a resistance state of the memory resistor 14 is switchable between two different resistance states (a high or reset resistance state and a low or set resistance state) using voltages having the same polarity. In this context, “resistance properties,” or “resistance characteristics,” refers to the memory resistor's response to a particular applied voltage or voltages in a particular voltage range. Thus, the different resistance characteristics of the memory resistor 14 refer to the memory resistor's different response to the same voltage (or voltages in the same range) depending on the resistance state of the device.

In FIG. 2A, when the memory resistor 14 is in a set state and a voltage applied to the memory resistor 14 increases, the resultant current increases as indicated by arrow 3. When the applied voltage reaches a first threshold voltage V_{RESET}, the resistance increases abruptly as indicated by arrow 4, and the memory resistor 14 transitions into the reset state. In the reset state, when a voltage applied to the memory resistor 14 increases, the resultant current increases as indicated by arrow 1. When the applied voltage reaches a second threshold voltage V_{SET}, the resistance of the memory resistor 14 decreases abruptly as indicated by arrow 2, and the memory resistor 14 transitions to the set state.

Still referring to FIG. 2A, in this example embodiment, when in the reset state the memory resistor 14 exhibits the resistance characteristics shown by path 1 in response an applied voltage between 0 and V_{SET} volts. When in the set state, however, the memory resistor 14 exhibits the resistance characteristics shown by path 3 in response an applied voltage between 0 and V_{RESET} volts, wherein V_{RESET} is less than V_{SET}. Thus, the memory resistor 14 exhibits different resistance characteristics in response to the same voltages in the same voltage range (e.g., between 0 and V_{RESET} volts) depending on the resistance state of the memory resistor 14.

Referring to FIG. 2B, the switch region 12 exhibits bi-polar properties or characteristics. A material having bi-polar properties or characteristics refers to a material in which the resistance characteristics or resistance state of the material is switched in response to voltages having different polarities. For example, a bi-polar material transitions to a low resistance (or set) state in response to a positive voltage greater than a positive threshold voltage (e.g., +V_{TH} volts), and transitions to a high resistance (or reset) state in response to a negative voltage lower than a negative threshold voltage (e.g., −V_{TH} volts).

In FIG. 2B, when a voltage applied to the switch region 12 in a reset state increases, the resultant current increases as indicated by arrow 1. When the applied voltage reaches the positive threshold voltage +V_{TH}, the resistance decreases abruptly as indicated by arrow 2, and the switch region 12 transitions into the set state. When a voltage applied to the switch region 12 decreases, the resultant current decreases as indicated by arrow 3.

When a magnitude of the negative voltage applied to the switch region 12 in the set state increases, the resultant current increases as indicated by arrow 4. When the applied negative voltage reaches a negative threshold voltage −V_{TH}, the resistance increases abruptly as indicated by arrow 5, and the switch region 12 transitions into the reset state. In the reset state, when the negative applied voltage is decreased to 0 V, the resultant current decreases along a path indicated by arrow 6.

Still referring to FIG. 2B, the switch region 12 transitions between a set and reset state in response to voltages having different polarities. When in the reset state the switch region 12 exhibits the resistance characteristics shown by paths 1 or 6 in response an applied voltage between −V_{TH} and +V_{TH}. When in the set state, however, the switch region 12 exhibits the resistance characteristics shown by paths 3 or 4 in response an applied voltage between −V_{TH} and +V_{TH}.

Electrical properties of an RRAM including the memory resistor 14 and the switch region 12 as shown in FIGS. 2A and 2B may be combined resulting in the electrical properties illustrated in FIG. 2C. For example, the memory resistor 14 and the switch region 12 may be placed in series.

FIG. 2C is a graph illustrating operational properties or characteristics of the RRAM of FIG. 1. Referring to FIG. 2C, electrical properties including electrical properties of reset and set states are observed in a +V region, whereas only high resistance state (HRS) properties are observed in a −V region. Thus, the RRAM operates in a manner similar to or the same as if it included a diode, but does not include the bilayer structure of a conventional diode. The RRAM according to at least this example embodiment may be used as a memory having relatively high and relatively low resistance states by changing the resistive properties of the memory resistor 14 in the +V region, but may have relatively high resistance to being switched off in the −V region.

When a plurality of cells each including the RRAM of FIG. 1 are formed in an array structure, interference between unit cells may be suppressed and/or prevented due to relatively high resistance of a switch-off state.

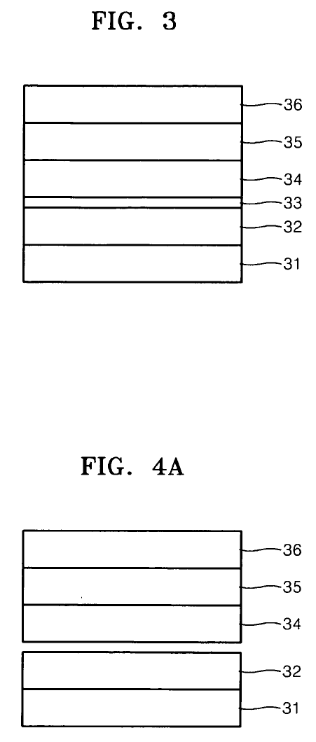

FIG. 3 is a cross-sectional view of a RRAM according to another example embodiment. Referring to FIG. 3, switch regions 32 and 33 may be formed on a lower electrode 31. An intermediate electrode 34, a memory resistor 35 and an upper electrode 36 may be formed on the switch regions 32 and 33.

The lower electrode 31, the intermediate electrode 34 and the upper electrode 36 may be formed of a conductive material used to form an electrode of a semiconductor device. For example, the conductive material may include Al, Hf, Zr, Zn, W, Co, Au, Ag, Pd, Pt, Ru, Ir, Ti, a conductive metal oxide or similar material. The memory resistor 35 may be formed of a variable resistance material. For example, the variable resistance material forming the memory resistor 35 may include a TMO.

The switch regions 32 and 33 may be formed of a nano switch material formed of a quantized conductance atomic switch (QCAS) material. For example, an intermediate layer 32 may be formed of an electrolyte material such as AgS, As₂S, GsSe or the like. A nano bridge 33 may be formed of Ag or the like. The nano bridge 33 may be formed to a relatively small (e.g., very small) thickness. For example, the nano bridge 33 may be formed of Ag to a thickness less than or equal to several tens of nm. In this example, the lower electrode 31 may also be formed of Ag.

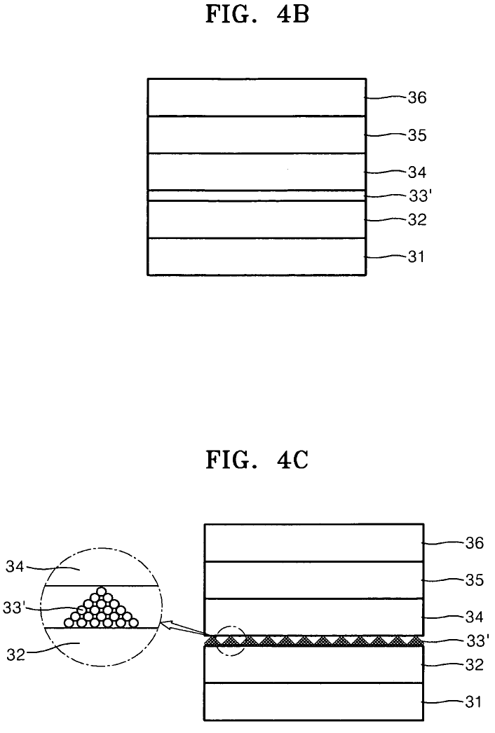

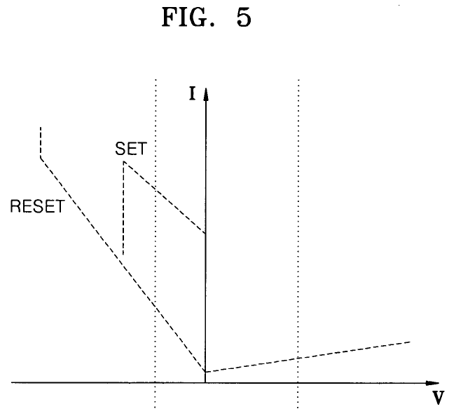

FIG. 4A is a cross-sectional view of the RRAM of FIG. 3 in the case where the switch regions 32 and 33 are switched off. FIGS. 4B and 4C are cross-sectional views of the RRAM of FIG. 3 in the case where the switch regions 32 and 33 are switched on. FIG. 5 is a graph illustrating electrical properties of the RRAM of FIG. 3. With reference to FIGS. 4A through 4C and 5, an operating principle of the RRAM will be described.

Referring to FIG. 4A, when +V is applied to the memory resistor 35 through the lower electrode 31 and the upper electrode 36, Ag of the nano bridge 33 moves to the intermediate layer 32. If the nano bridge 33 is formed of Ag and to a relatively small thickness (e.g., about 1 nm), Ag+ ions move to the intermediate layer 32 due to +V. As a result, a physical vacant space may be formed between the intermediate layer 32 and the intermediate electrode 34. Thus, as illustrated in FIG. 5, resistance is increased (e.g., greatly increased), and the RRAM switches off in a +V region.

Referring to FIG. 4B, when −V is applied to the memory resistor 35 through the lower electrode 31 and the upper electrode 36, Ag+ ions of the intermediate layer 32 move to an upper portion of the intermediate layer 32 to form a nano bridge 33′, which is illustrated in detail in FIG. 4C. As shown, a nano bridge 33′ having a pyramidal shape is formed due to Ag+ ions moving to the upper portion of the intermediate layer 32 in response to −V being applied.

As illustrated in FIG. 5, because resistance of the switch regions 32 and 33 is reduced in response to −V, uni-polar properties are observed according to the electrical properties of the memory resistor 35.

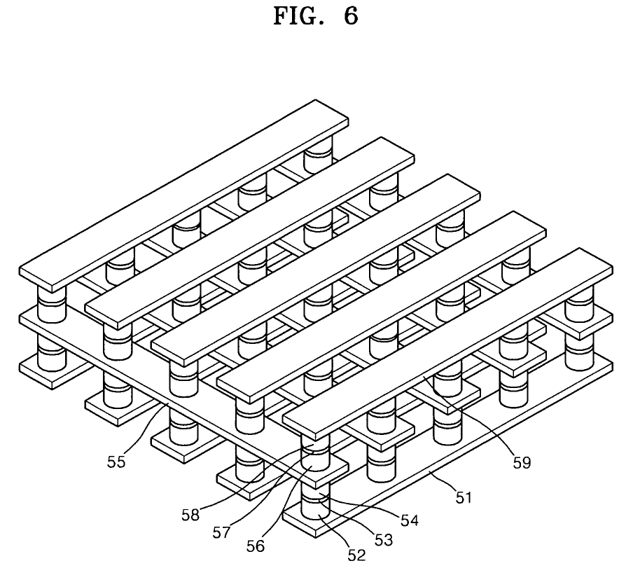

FIG. 6 illustrates the case where RRAMs, each of which corresponds to the RRAM of FIG. 1, are arranged in a multi-array or stacked-array structure, according to an example embodiment. The RRAMs may be arranged in an array structure including a plurality of unit cells, or in a multi-array structure in which arrays are arranged in a multi-array structure. Although FIG. 6 includes RRAMs of FIG. 1, the RRAMs of FIGS. 3-4C may also be included in the structure shown in FIG. 6.

Referring to FIG. 6, second electrode lines 55 formed in a second direction may be formed on first electrode lines 51 formed in a first direction. The multi-array structure may be formed such that switch regions 52, intermediate electrodes 53 and memory resistors 54 are formed at intersections between the first electrode lines 51 and the second electrode lines 55. Third electrode lines 59 formed in the first direction may be formed on the second electrode lines 55, and switch regions 56, intermediate electrodes 57 and memory resistors 58 may be formed on intersections between the second electrode lines 55 and the third electrode lines 59.

Without the switch regions 52 and 56, it may be relatively difficult to store and reproduce data due to interference between memory cells in a high resistance state (HRS). However, according to the one or more of the above-described example embodiments, a RRAM includes a switch region formed in a relatively simple structure, which exhibits relatively stable switching properties, which may reduce interference between memory cells.

It should be understood that the example embodiments described herein should be considered in a descriptive sense only and not for purposes of limitation. Descriptions of features or aspects within each example embodiment should typically be considered as available for other similar features or aspects in other example embodiments.

What is claimed is:

1. A resistive random access memory (RRAM) comprising:
a switch region formed of a material having bi-polar properties; and
a memory resistor formed of a material having uni-polar properties.

2. The RRAM of claim 1, wherein the switch region is formed of at least one of SiO₂, CuO, SrZrO₃, SrTiO₃, SrLaTiO₃, PrCaMnO, ZrO₂, TiO₂ and TiON.

3. The RRAM of claim 1, wherein the memory resistor includes at least one of a Ni oxide, a Ni oxide doped with Ti, a Co oxide, a Hf oxide, a Zn oxide, a W oxide, a Nb oxide, an Al oxide, a V oxide, a Cr oxide, a Fe oxide and a Ta oxide.

4. The RRAM of claim 1, further comprising:
a lower electrode formed below the switch region;
an upper electrode formed on the memory resistor; and
an intermediate electrode formed between the switch region and the memory resistor.

5. A multi-array resistive random access memory (RRAM) structure comprising:
a plurality of the RRAMs of claim 1 arranged in an array.

6. A resistive random access memory (RRAM) comprising:
a switch region including,
an intermediate layer including an electrolyte, and
a nano bridge formed on the intermediate layer; and
a memory resistor having variable resistance properties.

7. The RRAM of claim 6, wherein the intermediate layer is formed of AgS, As₂S or GsSe.

8. The RRAM of claim 6, wherein the nano bridge is formed of Ag.

9. The RRAM of claim 6, wherein the memory resistor includes at least one of a Ni oxide, a Ni oxide doped with Ti, a Co oxide, a Hf oxide, a Zn oxide, a W oxide, a Nb oxide, an Al oxide, a V oxide, a Cr oxide, a Fe oxide and a Ta oxide.

10. The RRAM of claim 6, further comprising:
a lower electrode formed below the switch region;
an upper electrode formed on the memory resistor; and
an intermediate electrode formed between the switch region and the memory resistor.

11. The RRAM of claim 6, wherein the switch region is formed of a nano switch material.

12. The RRAM of claim 11, wherein the nano switch material is formed of a quantized conductance atomic switch (QCAS) material.

13. A multi-array resistive random access memory (RRAM) structure comprising:
a plurality of the RRAMs of claim 6 arranged in an array.
